(19) United States
(12) Patent Application Publication
(10) Pub. No.: US 2006/0180932 A1
(43) Pub. Date: Aug. 17, 2006

(54) Component arrangement for series terminal for high-voltage applications

(76) Inventors: Ralf Otremba, Kaufbeuren (DE); Khalil Hosseini, Weihmichl (DE); Helmut Strack, Muenchen (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/328,595

(22) Filed: Jan. 10, 2006

(30) Foreign Application Priority Data
Jan. 10, 2005 (DE) 10 2005 001 151.9

(51) Int. Cl. H01L 23/52

(52) U.S. Cl. 257/758

(57) ABSTRACT

One embodiment of the invention relates to a component arrangement having a semiconductor chip, a chip carrier, a contact piece and a package. The semiconductor chip includes a first load terminal, a second load terminal and a control terminal, with the first load terminal and the second load terminal being arranged on mutually opposite sides of the semiconductor chip. The semiconductor chip is arranged on the chip carrier and is electrically and thermally conductively connected to the first load terminal. The contact piece is arranged on the second load terminal and is electrically and thermally conductively connected to it. The package is formed from a dielectric compound, which surrounds the semiconductor chip, the chip carrier and the contact piece. The chip carrier is exposed on a first side of the package, the contact piece is exposed on a second side of the package opposite the first side. A connecting leg is passed out of the package and is electrically conductively connected to the control terminal. One embodiment of the invention furthermore relates to a component cascade, in which a plurality of component arrangements are arranged on one another in the form of a stack.

### CROSS-REFERENCE TO RELATED APPLICATIONS

This Utility Patent Application claims priority to German Patent Application No. DE 10 2005 001 151.9, filed on Jan. 10, 2005, which is incorporated herein by reference.

### BACKGROUND

The invention relates to a component arrangement for series terminal in high-voltage applications. In order to switch high voltages of up to several hundred kV, component arrangements are normally connected in series with one another, so that the voltage to be switched by a single component arrangement is less than the overall voltage to be switched.

In order to provide a series circuit such as this, the individual semiconductor components are electrically conductively connected to one another. However, the lines that are used for this purpose on the one hand increase the electrical resistance of the circuit, and on the other hand make it harder to dissipate the heat losses that occur in the semiconductor components. Furthermore, the production of such lines is highly complex.

### SUMMARY

One embodiment of the present invention provides a component arrangement that is suitable for series terminal to identical or similar component arrangements, in which the heat losses that are produced are dissipated well, and that can be manufactured economically.

A component arrangement according to one embodiment of the invention includes a semiconductor chip that has a first load terminal, a second load terminal and a control terminal. In this case, the first load terminal and the second load terminal are arranged on mutually opposite sides of the semiconductor chip.

The semiconductor chip is arranged on a chip carrier and is electrically and thermally conductively connected to the first load terminal of the semiconductor body. A contact piece is arranged on the second load terminal and is electrically and thermally conductively connected to it.

The semiconductor chip, the chip carrier and the contact piece are surrounded by a dielectric compound that forms a package. The chip carrier is exposed on a first side of the package, and the contact piece is exposed on a second side of the package opposite the first side. A connecting leg, which is passed out of the package, is electrically conductively connected to the control terminal.

Since the contact piece extends from the semiconductor chip to the side opposite the chip carrier, the component arrangement has two load terminal surfaces that are arranged on mutually opposite sides, one of which is formed by the chip carrier and the other of which is formed by the contact piece.

It is thus possible to place two or more such component arrangements on one another in the form of a stack and to connect them electrically in series by positioning the matching load terminal surfaces of adjacent component arrangements such that they face one another, and by electrically connecting them to one another. In one embodiment, a pressure contact is suitable for this purpose. However, soldered joints or adhesive joints can just as well be used for this purpose.

Furthermore, electrically conductive intermediate pieces can also be arranged between the load terminal surfaces.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a cross section through a component arrangement according to one embodiment of the invention.

FIG. 2 illustrates a perspective view of a component arrangement according to one embodiment of the invention, with the package removed.

FIG. 3 illustrates a cross section through the component arrangement as illustrated in FIG. 2, but with the package illustrated.

FIG. 4 illustrates the component arrangement as illustrated in FIG. 3, in which the contact piece includes two sections.

FIG. 5 illustrates a component cascade having a plurality of semiconductor components as illustrated in FIG. 4, which are arranged on one another like a stack and are connected in series.

FIG. 6 illustrates a cross section through two identical component arrangements that can be cascaded, in each of which the first connecting contact projects beyond the first side of the package, and in which the second connecting contact is recessed with respect to the surface of the package.

FIG. 7 illustrates a cross section through a component arrangement in which the first connecting contact and the second connecting contact project beyond the package.

FIG. 8 illustrates a component arrangement corresponding to FIGS. 2 and 3, which is produced on the basis of a standard transistor package.

FIG. 9 illustrates a component arrangement in which the contact piece has depressions on its side facing away from the semiconductor chip, in which depressions a molding compound which forms the package engages in order to increase the strength of the joint between the contact piece and the package.

FIG. 10 illustrates a component arrangement in which the contact piece has projections that engage in the molding compound which forms the package, in order to increase the strength of the joint between the contact piece and the package.

FIG. 11 illustrates a perspective view of a component arrangement in which the contact piece and the chip carrier project beyond the surface of the package.

FIG. 12 illustrates a component arrangement in which the contact piece has a spring element.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

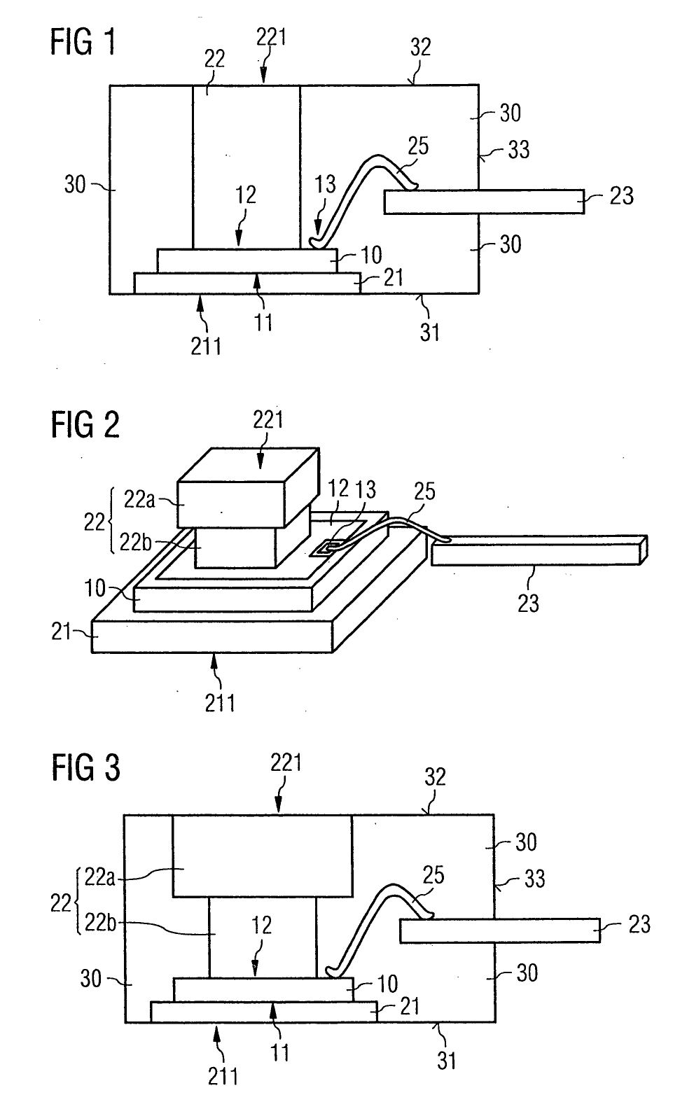

FIG. 1 illustrates a cross section through a component arrangement according to one embodiment of the invention, which includes a semiconductor chip 10, which in one case is in the form of a vertical semiconductor component, and has a first load terminal 11, a second load terminal 12 and a control terminal 13.

The first load terminal 11 is arranged on the opposite side of the semiconductor chip 10 to the second load terminal 12. The first load terminal 11 may, for example, be the drain terminal of a MOSFET, and the second load terminal 12 may be the source terminal of a MOSFET.

The semiconductor chip 10 is arranged on a chip carrier 21, and its first load terminal 11 is mechanically and electrically conductively connected to the chip carrier 21. In one case, a metallic contact piece 22 is arranged on the second load terminal 12, and is electrically connected to it. The terminal between the first load terminal 11 and the chip carrier 21 and/or between the second load terminal 12 and the contact piece 22 is in one case in the form of a soldered joint, by means of a solder, or an adhesive joint by means of a conductive adhesive. The contact piece is in one embodiment cuboid or cylindrical, and in one case with rounded corners and/or edges.

A rear surface 211 (which faces away from the semiconductor chip 10) of the chip carrier and a front surface 221 (which faces away from the semiconductor chip 10) of the contact piece 22 are not surrounded by the package 30 and represent the external contacts for the load path of the component arrangement. The rear surface 211 is arranged on a first side 31 of the package 30, and the front surface 221 is arranged on a second side 32 of the package 30, opposite the first side 31.

The heat losses that are produced in the semiconductor chip 10 can be dissipated not only via the chip carrier 21 and the rear surface 211 but also via the contact piece 22 and the front surface 221. In order to ensure a good electrical contact and heat transference that is as good as possible, the rear surface 211 and the front surface 221 are in one embodiment designed to have a large area.

The component arrangement furthermore has a connecting leg 23, which projects out of the package 30 and is electrically conductively connected to the control terminal 13 by means of a bonding wire 25. The connecting leg 23 is in one embodiment passed out in a lateral direction from an end face 33 of the package 30.

FIG. 2 illustrates a perspective view of a component arrangement according to one embodiment of the invention, with the package removed. A second load terminal 12 as well as a control terminal 13 are arranged on the side of the semiconductor chip 10 facing the contact piece 22. The first load terminal 11 is located on the side of the semiconductor chip 10 opposite the second load terminal 12, and cannot be seen in this view.

In contrast to the contact piece 22 illustrated in FIG. 1, the contact piece 22 illustrated in FIG. 2 is stepped and has a first section 22a as well as a second section 22b, which is arranged between the first section 22a and the semiconductor chip 10.

The side dimensions of that section 22b of the contact piece 22 that are closest to the semiconductor chip 10 result from the geometry of the second connecting contact 12. In order nevertheless to obtain as large a front area 221 as possible, that side of the contact piece 22 or of the first section 22a of the contact piece that faces away from the semiconductor chip 10 has an area that is larger than the contact area between the second load terminal 12 and the contact piece 22. The first and the second section 22a, 22b of the contact piece 22 are in one embodiment arranged in steps on one another.

Instead of two sections 22a, 22b, a contact piece can also have a plurality of such sections, which are in one case arranged in steps on one another.

FIG. 3 illustrates a cross section through the component arrangement as illustrated in FIG. 2, with the package 30 also being illustrated here.

The component arrangement has a dielectric package 30, that in one embodiment is formed from a molding or encapsulation compound, for example from plastic, ceramic, glass or a mixture of these substances. The rear surface 211 of the chip carrier 21 is arranged on the first side 31 of the package 30 and is exposed there in order to allow external contact to be made with the chip carrier 21. The contact piece 22 extends from the semiconductor chip 10 to the second surface 32 of the package 30 and is exposed there, in order to allow external contact to be made with the component arrangement.

The contact piece 22 is in one embodiment stepped with one or more steps, with that side 221 of the contact piece 22 that faces away from the semiconductor chip 10 in one embodiment having a larger area than the side of the contact piece 22 that faces the semiconductor chip 10.

The stepped design of the contact piece 22 allows the control terminal 13 to be arranged underneath the first section 22a of the contact piece 22.

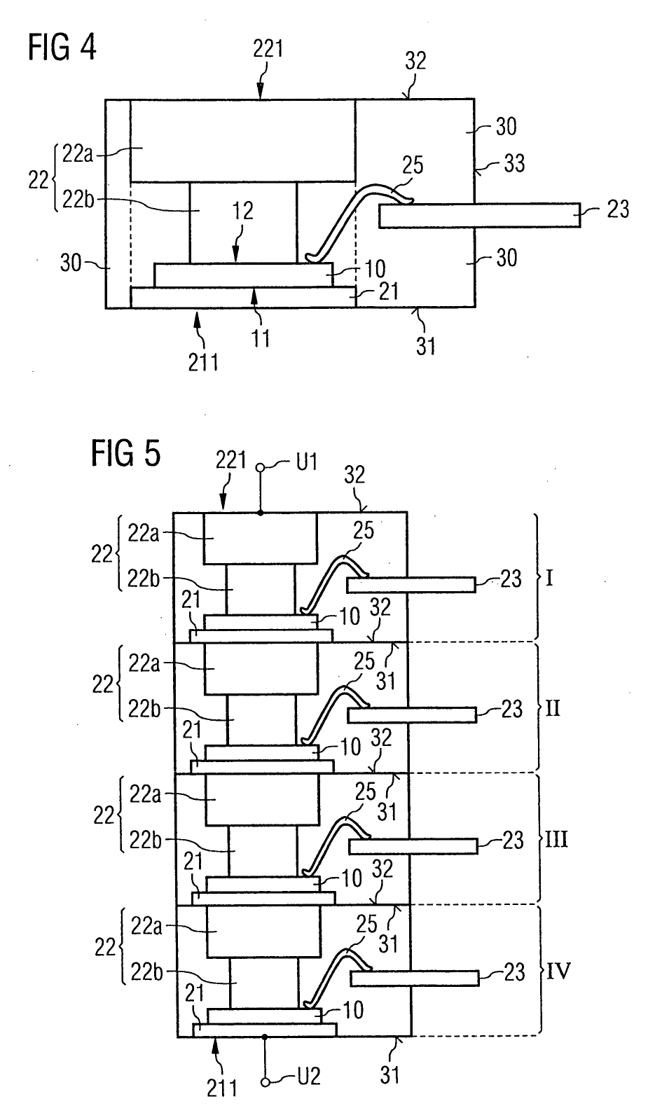

The first section 22a and the second section 22b may both be formed integrally or—as is illustrated in FIG. 4—from a plurality of pieces. The second section 22b is in one embodiment in the form of metallization, for example composed of copper or a copper alloy, on the second load terminal 12. The first section 22a and the second section 22b of the contact piece 22 are in one embodiment connected by means of a solder or by means of an electrically conductive adhesive.

Since the external contacts 211, 221 (which are connected to the load terminals 11, 12) of the component arrangement are located on mutually opposite sides 31, 32 of the component arrangement, a plurality of such component arrangements can be placed on one another like a stack, so that a chip carrier 21 of a first component arrangement I makes a thermal and electrically conductive contact with a contact piece 22 of an adjacent second component arrangement II.

Optionally, it is also possible for the two chip carriers 21 or the two contact pieces 22 of two adjacent component arrangements I, II to make thermal and electrically conductive contact with one another.

The contact between two adjacent component arrangements I, II is in one embodiment made by means of a pressure contact, although it is likewise possible to connect adjacent component arrangements I, II to one another by means of a solder or a conductive adhesive.

A cascaded arrangement of two or more component arrangements I, II, III and IV such as this results in a series circuit, so that the difference between a first supply potential that is applied to the contact piece 22 of the uppermost component arrangement I and a second supply potential U2 that is applied to the chip carrier 21 of the lowermost component arrangement IV is distributed between the individual component arrangements I, II, III, IV.

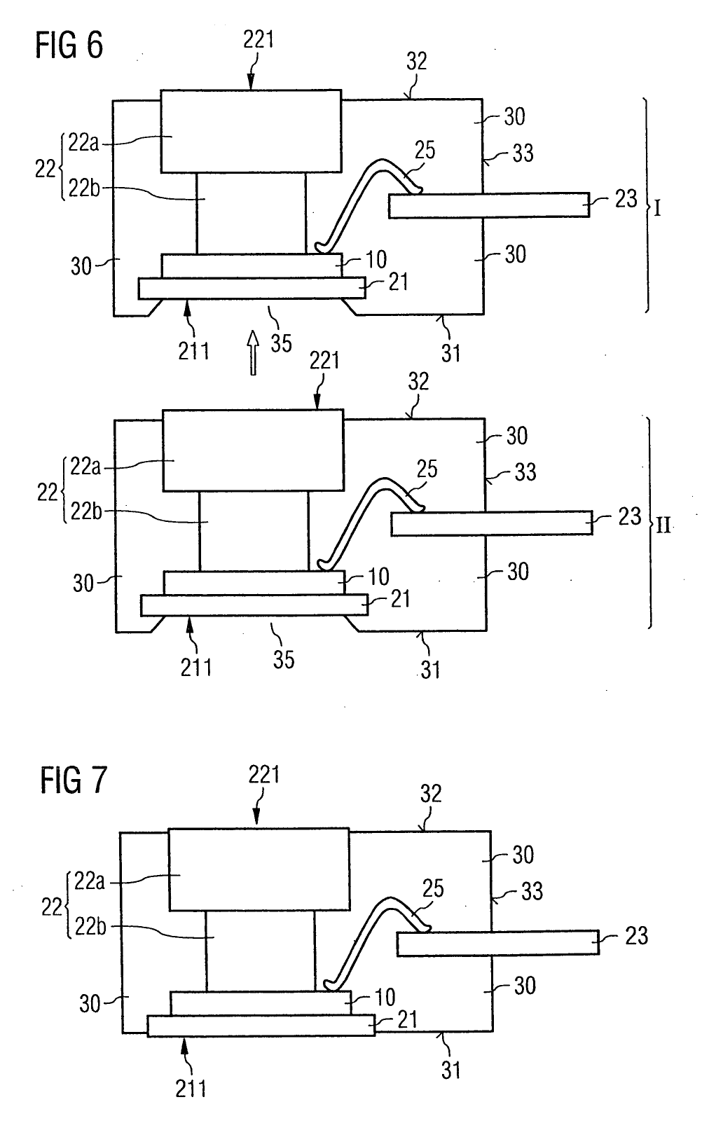

In order to simplify the stacking capability of such component arrangements, provision is optionally made for the contact piece 22 to project beyond the second side 32 of the package 30. If the chip carrier 21 is at the same time recessed with respect to the first side 31 of the package 30, then a contact piece which projects beyond the package 30 of another component arrangement can be positioned precisely in the depression 35 that is created, as is illustrated in FIG. 6. Once a first component arrangement I and a second component arrangement II have been joined together, the front surface 221 of the second component arrangement II makes contact with the rear surface 211 of the first component arrangement I.

As an alternative to this, it is also possible for the chip carrier 21 to project beyond the first side 31 of the package 30, and for the contact piece 22 to be recessed with respect to the second side 32 of the package 30.

In order to ensure safe and reliable contact between successively arranged component arrangements, particularly when a pressure contact is used, in one embodiment the chip carrier 21 projects beyond the first side 31, and also the contact piece 22 projects beyond the second side 32 of the package 30. A component arrangement such as this is illustrated in FIG. 7.

FIG. 12 illustrates a component arrangement that has been modified from the component arrangement illustrated in FIG. 6 and in which the contact piece has a spring element 22c that, in the example, is arranged between the first and the second section 22a, 22b of the contact piece 22. The first section 22a is in this case arranged such as it can be moved in the vertical direction in a cutout in the package. When a plurality of such component arrangements are cascaded, the first section is pressed by the spring element 22c against the rear surface 211 of the further component arrangement. The spring element 22c thus ensures optimum contact between adjacent contact surfaces when a plurality of component arrangements are cascaded.

As is illustrated in FIG. 12, the spring element may be provided in addition to the first and the second section 22a, 22b of the contact piece 22. It is also possible, but in a manner that is not illustrated, for one of the two sections 22a, 22b to be in the form of a spring element, or for the entire contact piece to be in the form of a spring element. In this case, any desired element that can be compressed in one direction when loaded in compression is suitable for use as the spring element, provided that it is also composed of an electrically conductive material.

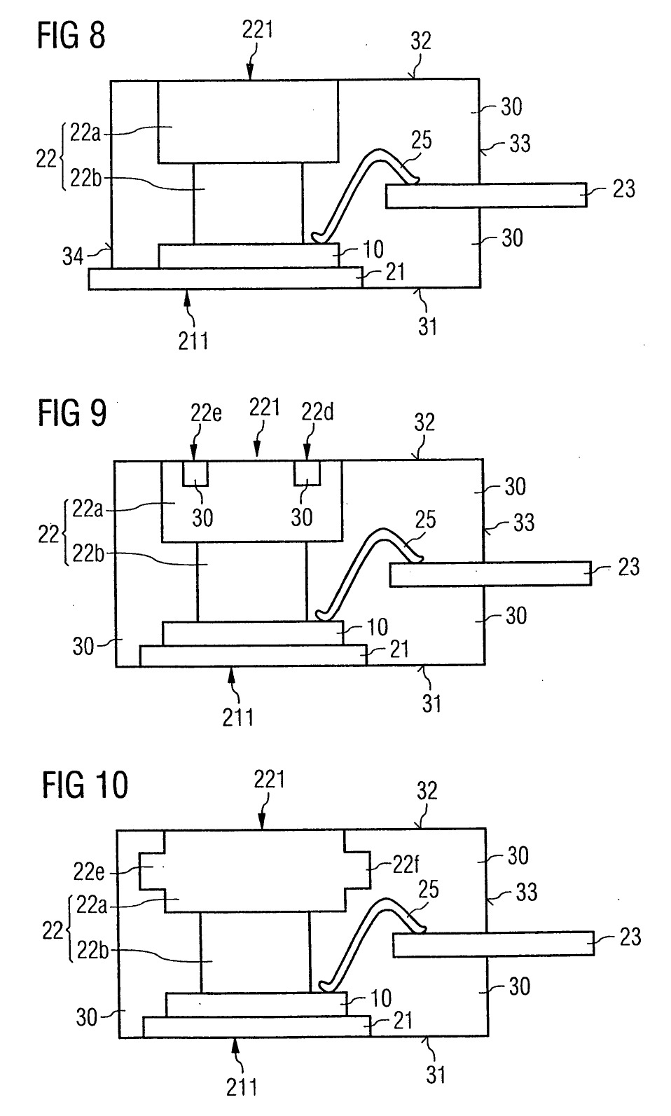

In order to minimize the effort required for production of a component arrangement according to one embodiment of the invention, use is made of a modified standard package. FIG. 8 illustrates a cross section through a conventional TO series transistor package. The chip carrier 21 in this case projects beyond the package 30 in a lateral direction on one end face 34 of the package 30.

In order to improve the adhesion to the package 30, the contact piece 22 may have any desired surface structure.

FIG. 9 illustrates a cross section through a component arrangement in which the contact piece 22 has depressions or grooves 22c, 22d. In this exemplary embodiment, the grooves 22c, 22d are arranged on the side of the contact piece 22 facing away from the semiconductor chip 10. In principle, the grooves and depressions 22c, 22d may, however, be arranged at any desired points on the contact piece 22, for example on the side surfaces of the contact piece 22.

As is illustrated in FIG. 10, the contact piece 22 may also have projections 22e, 22f in order to improve its connection to the package 30. The projections 22e, 22f are in one embodiment arranged on the side surfaces of the contact piece 22, as illustrated. The number and the shape of the projections 22e, 22f may in principle be chosen as required.

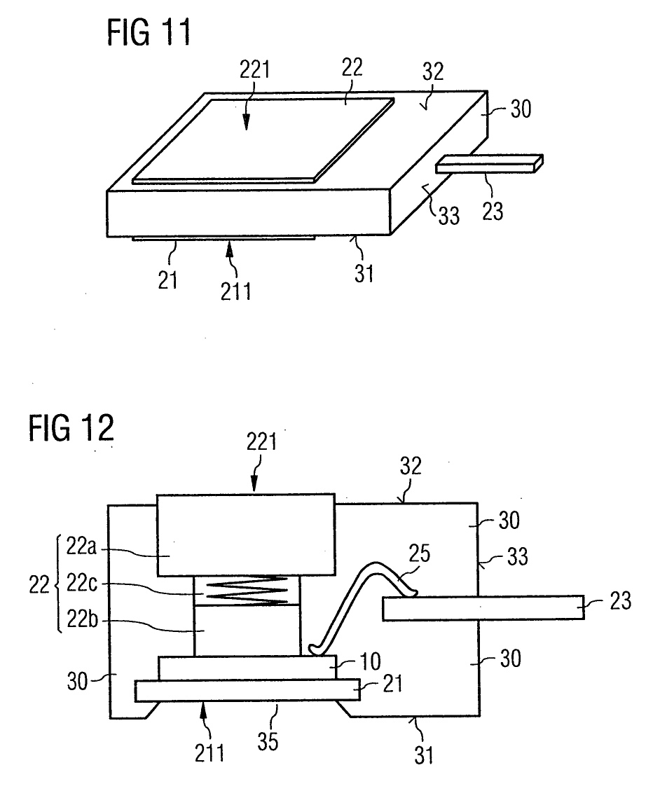

FIG. 11 illustrates a perspective view of a component arrangement. The chip carrier 21 projects beyond the first side 31, and the contact piece 22 projects beyond the second side 32. The area of the rear surface 211 is in one case identical to that of the front surface 221, or differs from it by less than 10%.

Component arrangements such as these are in some embodiments produced using a so-called “leadframe”, which includes a plurality of chip carriers connected to one another, with one semiconductor chip being arranged on each chip carrier.

In order to produce a component arrangement according to one embodiment of the invention, semiconductor chips are first of all soldered to the chip carriers. After this, the bonding terminals are produced between the control terminals and the respective connecting legs. The contacts and/or connections are then made between the contact pieces and the relevant second load terminals.

After this, the packages are produced by the semiconductor chips, the leadframe, the contact pieces and the bonding wires being at least partially extrusion coated or encapsulated with a dielectric sprayed or encapsulation compound (film molding process). In order to keep the front surfaces and the rear surfaces free of the sprayed or encapsulation compound, they are in some embodiments covered with a protective film.

Before or after the removal of the protective film, the component arrangements are separated by cutting through webs that connect the chip carriers.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A component arrangement comprising:
a semiconductor chip having a first load terminal, a second load terminal and a control terminal, the first load terminal and the second load terminal being arranged on mutually opposite sides of the semiconductor chip;
a chip carrier on which the semiconductor chip is arranged and which is electrically and thermally conductively connected to the first load terminal of the semiconductor chip;
a contact piece arranged on the second load terminal and electrically and thermally conductively connected to the second load terminal; and
a dielectric compound surrounding the semiconductor chip, the chip carrier and the contact piece thereby forming a package with the chip carrier being exposed on a first side of the package, the contact piece being exposed on a second side of the package opposite the first side and the control terminal being electrically conductively connected to a connecting leg which is passed out of the package.

2. The component arrangement of claim 1, wherein the contact piece has a front area that is larger than the area of the second load terminal, on its side facing away from the semiconductor chip.

3. The component arrangement of claim 1, wherein the contact piece has a first section and has a second section that is arranged between the first section and the semiconductor chip.

4. The component arrangement of claim 3, wherein the first section and the second section are arranged in steps on one another.

5. The component arrangement of claim 3, wherein the control terminal is arranged underneath the first section.

6. The component arrangement of claim 3, wherein the second section is in the form of metallization on the second load terminal.

7. The component arrangement of claim 3, wherein the second section is formed from copper or a copper alloy.

8. The component arrangement of claim 1, wherein the chip carrier is recessed with respect to the first side.

9. The component arrangement of claim 1, wherein the chip carrier projects beyond the first side.

10. The component arrangement of claim 1, wherein the contact piece is recessed with respect to the second side.

11. The component arrangement of claim 1, wherein the contact piece projects beyond the second side.

12. The component arrangement of claim 2, wherein depressions or grooves are arranged on the front area.

13. The component arrangement of claim 1, wherein the contact piece has projections that engage in the package.

14. The component arrangement of claim 2, wherein the chip carrier has a rear area on its side facing away from the semiconductor chip whose area is identical to the front area, or differs from it by less than 10%.

15. The component arrangement of claim 1, wherein the package is formed from a molding compound or an encapsulation compound.

16. The component arrangement of claim 1, wherein the contact piece comprises a spring element.

17. A component cascade comprising:
a first component arrangement; and
a second component arrangement stacked on the first component arrangement;
wherein each of the first and second component arrangements each comprise:
a semiconductor chip having a first load terminal, a second load terminal and a control terminal, the first load terminal and the second load terminal being arranged on mutually opposite sides of the semiconductor chip;
a chip carrier on which the semiconductor chip is arranged and which is electrically and thermally conductively connected to the first load terminal of the semiconductor chip;
a contact piece arranged on the second load terminal and electrically and thermally conductively connected to the second load terminal; and
a dielectric compound surrounding the semiconductor chip, the chip carrier and the contact piece thereby forming a package with the chip carrier being exposed on a first side of the package, the contact piece being exposed on a second side of the package opposite the first side and the control terminal being electrically conductively connected to a connecting leg which is passed out of the package; and
wherein the chip carrier of the second component arrangement is electrically conductively connected over an area of the contact piece of the second component arrangement.

18. A component arrangement comprising:
a semiconductor chip having a first and second load terminals and a control terminal;
a chip carrier on which the semiconductor chip is arranged and which is electrically and thermally conductively connected to the first load terminal of the semiconductor chip;
a contact piece arranged on the second load terminal and electrically and thermally conductively connected to the second load terminal; and
a package surrounding the semiconductor chip, the chip carrier and the contact piece, the package formed of a dielectric compound;
means for exposing the chip carrier on a first side of the package and for exposing the contact piece on a second side of the package opposite the first side; and
means for electrically conductively connecting to the control terminal from outside the package.

19. The component arrangement of claim 18, wherein the first load terminal and the second load terminal are arranged on mutually opposite sides of the semiconductor chip.

20. The component arrangement of claim 18, wherein the control terminal is electrically conductively connected to a connecting leg that is passed out of the package.
